(19) United States
(12) Patent Application Publication
(10) Pub. No.: US 2015/0121159 A1
(43) Pub. Date: Apr. 30, 2015

(54) SEMICONDUCTOR INTEGRATED CIRCUIT

(71) Applicant: Sony Corporation, Tokyo (JP)

(72) Inventors: Keita Izumi, Kanagawa (JP); Katsumi Takaoka, Kanagawa (JP); Toshiyuki Kouchiyama, Kanagawa (JP); Syunsuke Hamashima, Kagoshima (JP); Kouichirou Ono, Kagoshima (JP)

(21) Appl. No.: 14/508,588

(22) Filed: Oct. 7, 2014

(30) Foreign Application Priority Data
Oct. 24, 2013 (JP) 2013-220951

(51) Int. Cl. G01R 31/3177

(52) U.S. Cl. CPC G01R 31/3177
USPC 714/735

(57) ABSTRACT

There is provided a semiconductor integrated circuit, including a test circuit, a plurality of signal cells, a power supply cell, and a control circuit. The test circuit performs a predetermined test on a test target circuit. A plurality of signal cells input an input signal into the test circuit and the test target circuit. The power supply cell supplies power to some of the plurality of signal cells in the test. The control circuit controls a value of the input signal from signal cells that include signal cells to which the power is not supplied and that are not used in the test, to be a predetermined value.

### CROSS REFERENCE TO RELATED APPLICATIONS

This application claims the benefit of Japanese Priority Patent Application JP 2013-220951 filed Oct. 24, 2013, the entire contents of which are incorporated herein by reference.

### BACKGROUND

The present technology relates to a semiconductor integrated circuit, and more particularly, to a semiconductor integrated circuit performing a test.

In the related art, in a process of manufacturing a semiconductor, a wafer test is performed after a wafer is cut out from an ingot, a circuit pattern is formed on the wafer, or the like. In the wafer test, a test is performed on a plurality (for example, 2×2, a total of four) of semiconductor chips on the wafer at the same time so as to improve inspection efficiency. A plurality of electrode pads are provided in each of the semiconductor chips, and a probe card on which probes are disposed at positions corresponding to these electrode pads is used in the wafer test. In addition to the probes, a plurality of pin terminals connected to a tester and a wiring which connects probes to these pin terminals are provided on the probe card.

Here, a density of probes on the probe card is high in a configuration in which probes are provided on a probe card in all of the electrode pads on the semiconductor chips. Therefore, wirings between the probes and the pin terminals become complicated. When increasing the number of semiconductor chips to be tested at the same time, it is not possible to provide probes in all of the electrode pads. Then, a test system which performs a test not in all of the electrode pads but only in some electrode pads on the semiconductor chips has been proposed (for example, refer to Japanese Unexamined Patent Application Publication No. 2006-222200). According to the test system, since probes may be provided on a probe card only in some electrode pads on the semiconductor chips, a wiring on the probe card becomes simple and the number of semiconductor chips which can be tested at the same time is easily increased.

### SUMMARY

However, in the above-described technology of the related art, there is a possibility that an appropriate result in a wafer test may not be obtained. An input/output cell is provided in each of the electrode pads in semiconductor chips, and power is not supplied to an input/output cell which corresponds to an electrode pad that is not used in a test in some cases. Moreover, a probe card does not bring probes into contact with an input/output cell which is supplied with power but is not used in a test. There is a possibility that an input signal with an undetermined voltage level is input to a circuit in the semiconductor chips from these input/output cells which are not used in a test. There is a possibility that an accurate test result in the wafer test is not obtained due to this input signal.

It is desirable to obtain an appropriate result in a wafer test.

According to a first embodiment of the present technology, there is provided a semiconductor integrated circuit, including a test circuit which performs a predetermined test on a test target circuit, a plurality of signal cells which input an input signal into the test circuit and the test target circuit, a power supply cell which supplies power to some of the plurality of signal cells in the test, and a control circuit which controls a value of the input signal from signal cells that include signal cells to which the power is not supplied and that are not used in the test, to be a predetermined value. Accordingly, an action that a value of an input signal from the signal cells to which power is not supplied among the plurality of signal cells in a test is controlled to be a predetermined value is caused.

In the first embodiment, the semiconductor integrated circuit may be provided in a semiconductor chip of a rectangular shape, the plurality of signal cells may be arrayed along each of four sides of the semiconductor chip, and the power supply cell may supply the power to the signal cell arrayed along at least one of two sides of the semiconductor chip. Accordingly, an action that power is supplied to the signal cell arrayed along at least one of two sides of the semiconductor chip is caused.

In the first embodiment, the test target circuit may generate a control signal which instructs controlling the input signal to be the predetermined value, and an output signal to supply these signals to the signal cell, and the signal cell may control the input signal to be the predetermined value according to the control signal to output the output signal. Accordingly, the input signal is caused to be controlled to a predetermined value according to the control signal.

According to a second embodiment of the present technology, there is provided a test system, including a test circuit which performs a predetermined test on a test target circuit, a plurality of signal cells which input an input signal into the test circuit and the test target circuit, a power supply cell which supplies power to some of the plurality of signal cells in the test, a control circuit which controls a value of the input signal from signal cells that include signal cells to which the power is not supplied and that are not used in a test, to be a predetermined value, and a probe card on which a probe is provided at a position corresponding to each of some of the plurality of signal cells and the power supply cell. Accordingly, an action in which a value of an input signal from signal cells that include signal cells to which power is not supplied and that are not used in a test is controlled to be a predetermined value is caused.

According to the embodiments of the present technology, it is possible to achieve an excellent effect that an appropriate result in a wafer test can be obtained. Effects described herein are not necessarily limited, but may be any effect described in the present disclosure.

### BRIEF DESCRIPTION OF THE DRAWINGS

FIG. 1 is an overall view which shows a configuration example of a test system in a first embodiment;

FIG. 2 is an example of a plan view of the semiconductor chip in the first embodiment;

FIG. 3 is a circuit diagram which shows a configuration example of the semiconductor chip in the first embodiment;

FIG. 4 is a view which shows an example of a test area using two sides of the first embodiment;

FIG. 5 is a view which shows an example of a test area using one side of the first embodiment;

FIG. 6 is an example of a plan view of a probe card in the first embodiment;

FIG. 7 is an example of a plan view of a probe substrate in the first embodiment;

FIG. 8 is a circuit diagram which shows a configuration example of a semiconductor chip in a first modification example; and

FIG. 9 is a circuit diagram which shows a configuration example of a semiconductor chip in a second modification example.

### DETAILED DESCRIPTION OF EMBODIMENTS

Hereinafter, forms for performing the present technology (hereinafter, referred to as embodiments) will be described. The description will be performed in a following order.

1. First embodiment (an example of invalidating an input signal from some signal cells)

2. Modification example

### 1. First Embodiment

### Configuration Examples of a Test System

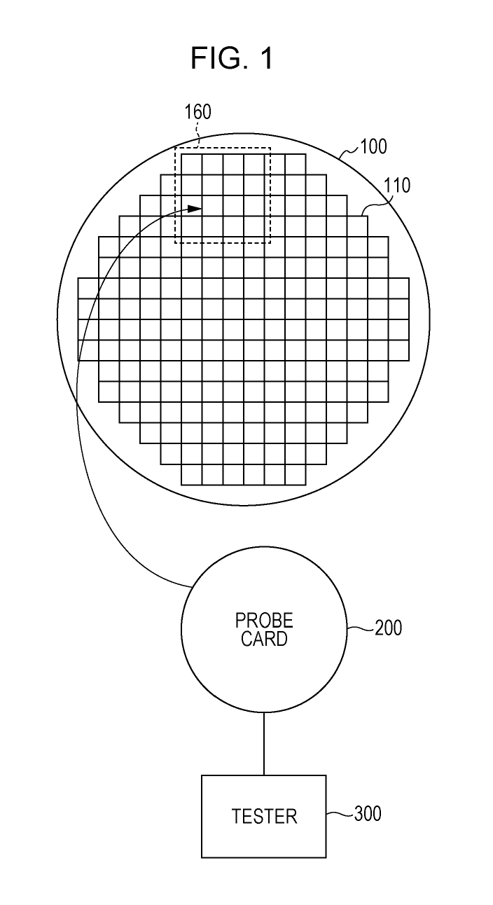

FIG. 1 is a block diagram which shows a configuration example of a test system in a first embodiment. The test system is a system for performing a wafer test, and includes a wafer 100, a probe card 200, and a tester 300.

The wafer 100 is a disc-shaped member cut from an ingot of a semiconductor. A plurality of semiconductor chips 110 are formed in the wafer 100. The semiconductor chip 110 is a rectangular shaped part in which a semiconductor integrated circuit is formed. An internal circuit, a plurality of electrode pads, and the like are formed in each of the plurality of semiconductor chips 110. These internal circuits and electrode pads are omitted in FIG. 1.

Here, a number of semiconductor chips 110 less than a predetermined number are simultaneously tested in a wafer test so as to improve test efficiency. A region having the same size as a region made of the maximum number of the semiconductor chips 110 which are simultaneously tested is referred to as “test region” 160 below. The test area 160 is a region having the same size as a region made of, for example, 4×4, a total of 16, semiconductor chips 110.

In a wafer test, a region which is made of only the semiconductor chips 110 that are not tested yet is set to be the test area 160, and when the test on the region is finished, the test area 160 is changed to another region on which the test is not performed yet. Then, until the test on all of the semiconductor chips 110 is finished, a change of the test area 160 and a test on the test area 160 are repeatedly performed.

The probe card 200 is a tool on which a plurality of probes are provided. These probes are provided at a position corresponding to an electrode pad on the semiconductor chips 110 in the test area 160. In addition, the probe card 200 is connected to the tester 300. In a wafer test, driving of a mounting stand and the like on which the wafer 100 is placed brings the probes on the probe card 200 into contact with each of electrode pads in the test area 160.

The tester 300 performs a test on internal circuits formed on the semiconductor chips 110. When a driving device brings probes into contact with an electrode pad, the tester 300 generates a test start signal to notify a start of a test and transmits the test start signal to each of the semiconductor chips 110 in the test area 160 through the probe card 200. Then, the tester 300 performs a test on electrical characteristics and the like of the internal circuit on the semiconductor chips 110.

### Configuration Examples of the Semiconductor Chip

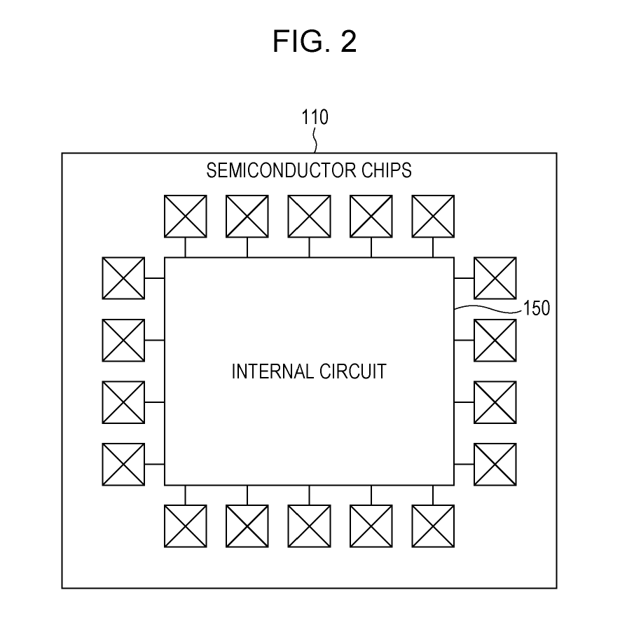

FIG. 2 is an example of a plan view of the semiconductor chips 110 in the first embodiment. The semiconductor chips 110 include a plurality of electrode pads 120 and an internal circuit 150. In addition, one input/output cell is provided at a bottom of each of the electrode pads 120, and each of the electrode pads 120 is connected to an input/output cell at the bottom thereof. These input/output cells are omitted in the same figure.

The electrode pads 120 are electrodes electrically connected to the probe card 200 by bringing the probes into contact therewith. Each of the electrode pads 120 is arrayed along, for example, each of the four sides of the semiconductor chips 110 of a rectangular shape. Moreover, each of the electrode pads 120 is connected to the internal circuit 150 through the input/output cell. The internal circuit 150 is a circuit formed on the semiconductor chips 110.

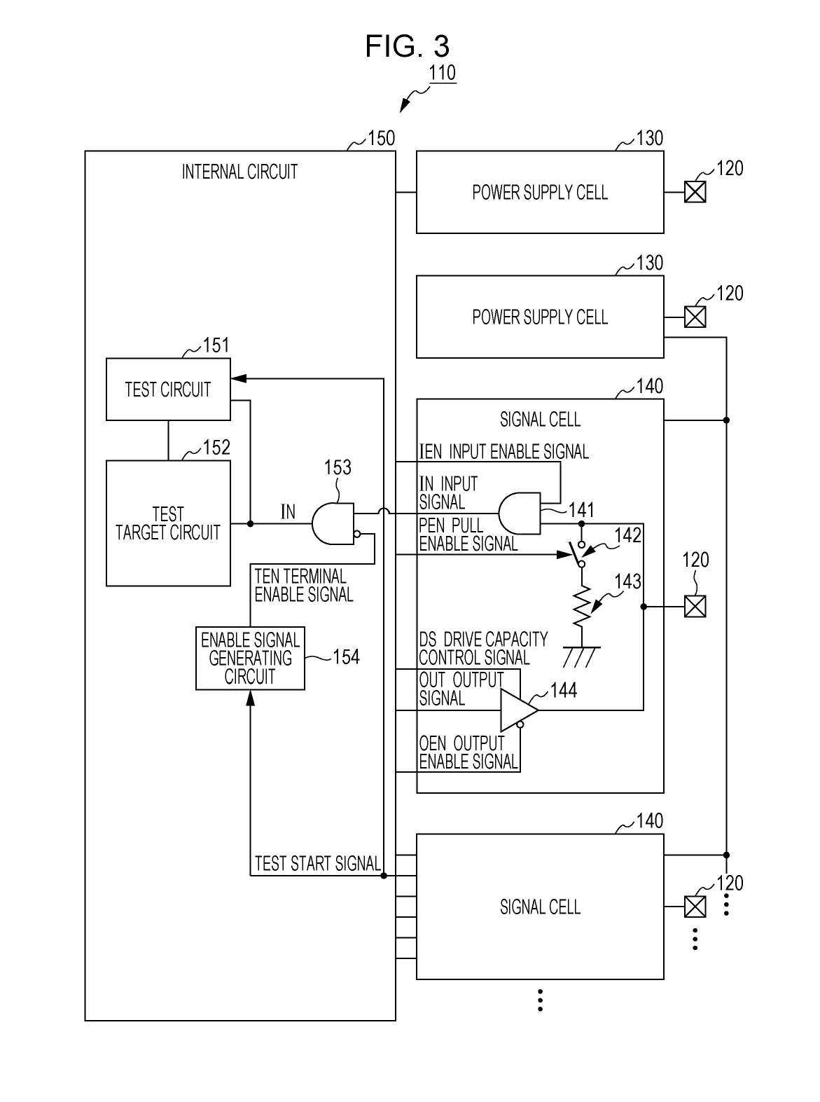

FIG. 3 is a circuit diagram which shows a configuration example of the semiconductor chips 110 in the first embodiment. The semiconductor chips 110 include a plurality of electrode pads 120, a plurality of power supply cells 130, a plurality of signal cells 140, and the internal circuit 150. The internal circuit 150 includes a test circuit 151, a test target circuit 152, and a plurality of AND (logical AND) gates 153.

The power supply cells 130 are input/output cells which supply power from the probe card 200 to the internal circuit 150 or the signal cells 140. One electrode pad 120 is connected to each of the power supply cells 130. The power supply cells 130 are provided in each of a plurality of groups made of the plurality of signal cells 140.

The power supply cells 130 supply power from the electrode pads 120 to the signal cells 140 in a corresponding group. Here, the probe card 200 does not bring probes into contact with the electrode pads 120 of the power supply cells 130 corresponding to signal cells 140 which are not used in a test. Therefore, among the signal cells 140 which are not used in the test, some signal cells are not supplied with power itself. In addition, the probe card 200 does not bring probes into contact with signal cells 140 which are supplied with power by the power supply cells 130, but are not used in the test.

Moreover, the power supply cells 130 corresponding to the signal cells 140 used in the test supplies power from the electrode pads 120 to not only these signal cells 140 but also to the internal circuit 150.

The signal cells 140 input or output a signal to or from the internal circuit 150. The signal cells 140 include an AND gate 141, a switch 142, a pull resistance 143, and a buffer 144.

The AND gate 141 outputs an input signal IN according to an input enable signal IEN. Here, the input enable signal IEN is a signal which instructs whether or not to invalidate an input signal IN, and is generated by the internal circuit 150. The input signal IN is a signal input from the electrode pads 120 to the internal circuit 150, and is generated by the tester 300. For example, when invalidating the input signal IN, the input enable signal IEN is set to be at a low level, and is set to be at a high level in the other cases. The test start signal is included in the input signal IN. The AND gate 141 has two input terminals, and the input enable signal IEN is input to one of these input terminals from the internal circuit 150, and the input signal IN is input to the other through the electrode pads 120. The AND gate 141 outputs a logical sum of these signals to the internal circuit 150 as the input signal IN.

The switch 142 connects the pull resistance 143 to an input terminal of the AND gate 141 according to a pull enable signal PEN. Here, the pull enable signal PEN is a signal which instructs whether or not to connect the pull resistance 143 to the input terminal of the AND gate 141, and is generated by the internal circuit 150 when necessary. The switch 142 has two terminals, and one of the terminals is connected to the pull resistance 143 and the other is connected to the input terminal of the AND gate 141 and the electrode pads 120. An input signal IN at an appropriate level is transferred by connecting the pull resistance 143 to the input terminal of the AND gate.

The pull resistance 143 is a resistance which is provided so as to set a voltage of the input signal IN to an appropriate level. One terminal of the pull resistance 143 is connected to the switch 142, and the other is applied with a reference potential (for example, a ground potential).

The buffer 144 outputs an output signal OUT according to a drive capacity control signal DS and an output enable signal OEN. Here, the output signal OUT is a signal output from the internal circuit 150 to the electrode pads 120, and is generated by the internal circuit 150 when necessary. The output enable signal OEN is a signal which instructs whether or not to invalidate an output signal OUT, and is generated by the internal circuit 150 when necessary. The drive capacity control signal DS is a signal which controls a voltage of the output signal OUT, and is generated by the internal circuit 150 when necessary.

The test circuit 151 performs a test on the test target circuit 152 according to a control of the tester 300. When receiving a test start signal from any one of the signal cells 140, the test circuit 151 starts a test on the test target circuit 152. The test circuit 151 performs processing of generating a test pattern, processing of checking a test result and an expectation value, or the like in a test. These processings are processings which are originally processed by the tester 300; however, since the test circuit 151 performs these processings instead of the tester 300, a burden of the tester 300 is reduced. In this manner, the test circuit 151 on the semiconductor chips 110 which performs a part of the function of the tester 300 is referred to as a Built-In Self Test (BIST) circuit.

The test target circuit 152 is a circuit which is generated so as to realize a predetermined function in the semiconductor chips 110.

The AND gate 153 invalidates the input signal IN from the signal cells 140 according to a terminal enable signal TEN. The AND gate 153 is provided, one for each of the signal cells 140. Here, the terminal enable signal TEN is a signal which instructs whether or not to invalidate the input signal IN, and is generated by the enable signal generating circuit 154. For example, when invalidating the input signal IN, the terminal enable signal TEN is set to be a high level, and is set to be a low level in the other cases. Here, “invalidating” the input signal IN means controlling a value of the input signal IN from the signal cell 140 to be a predetermined value (for example, “0”).

The AND gate 153 has two input terminals, and a signal obtained by inverting the terminal enable signal TEN is input to one of the terminals, and the input signal IN from the AND gate 141 is input to the other. The AND gate 153 supplies a logical sum of these signals to the test circuit 151 as the input signal IN. Power is supplied from any one of the power supply cells 130 to the AND gate 153 in the wafer test.

The input signal IN is invalidated by the AND gate 153; however, this technology is not limited to this configuration. For example, an OR gate or the like may be provided instead of the AND gate to invalidate the input signal IN. In addition, the AND gate 153 is an example of a control circuit described in claims.

When a test start signal is input, the enable signal generating circuit 154 generates an enable signal TEN which invalidates an input signal IN from the signal cells 140 which are not used in a test. The invalidated input signal IN is an input signal IN from the signal cells 140 which are arrayed along two sides which are parallel to each other among sides of the semiconductor chips 110 of a rectangular shape. The enable signal generating circuit 154 supplies the generated enable signal to each of the AND gates 153.

In this manner, by invalidating the input signal IN from the signal cells 140 which are not used in a test, it is possible to prevent an input signal IN at an undetermined level from being input to the test circuit 151 and the test target circuit 152. Accordingly, the test system can perform a wafer test with a high accuracy.

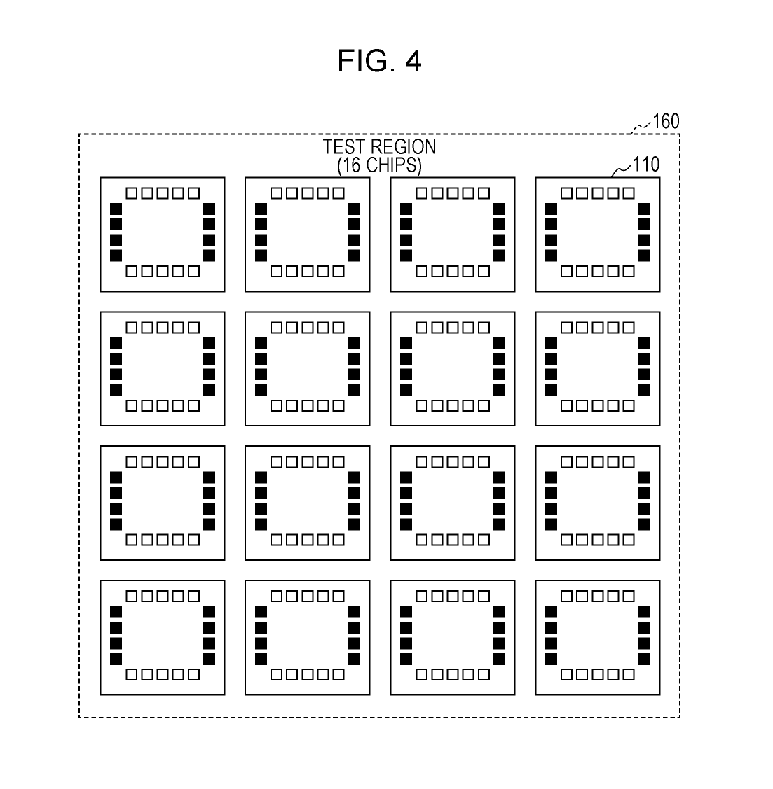

FIG. 4 is a view which shows an example of the test area 160 using two sides in the first embodiment. As shown in the same figure, the test area 160 is a region which has the same size as a region made of 4×4, a total of 16, semiconductor chips 110. A shape and a size of the test area 160 are not limited to the shape and the like exemplified in the same figure. For example, the test area 160 may have the same size as a region made of 16×1 or 2×2 semiconductor chips 110.

In FIG. 4, black squares on the semiconductor chips 110 represent electrode pads which are brought into contact with probes, and white squares represent electrodes which are not brought into contact with probes. As exemplified in the same figure, electrode pads along two sides which are parallel to each other among four sides of the semiconductor chips 110 are used as electrode pads which are brought into contact with probes. The electrode pads which are not brought into contact with probes are not used in the test, and an input signal IN from the electrode pads is set to be invalidated.

FIG. 4 adopts a configuration which uses two of four sides in a test; however, if using only some of the electrode pads, the technology is not limited to the configuration. For example, a configuration which uses only electrode pads arrayed along one of four sides may be adopted.

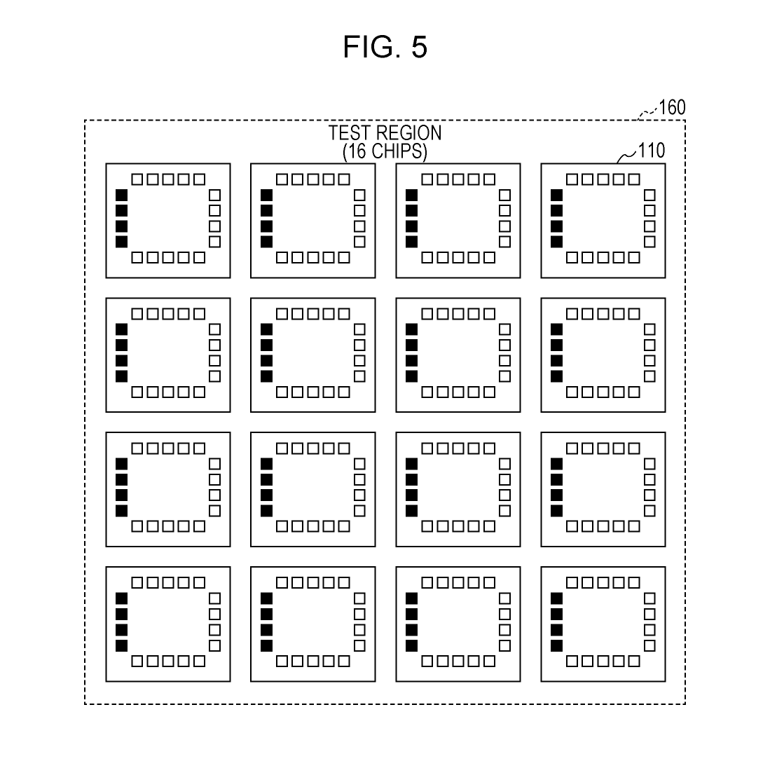

FIG. 5 is a view which shows an example of a test area which uses one side in the first embodiment. As exemplified in the same figure, electrode pads along one of four sides of the semiconductor chips 110 are used as electrode pads which bring probes in contact.

### Configuration Examples of Probe Card

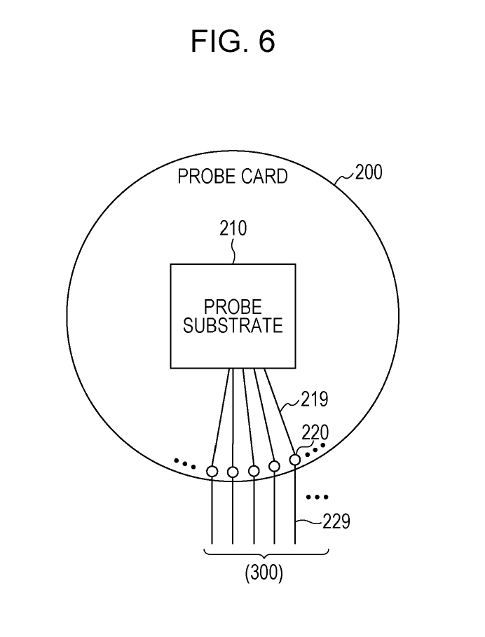

FIG. 6 is an example of a plan view of the probe card 200 in the first embodiment. The probe card 200 includes a probe substrate 210 and a plurality of pin terminals 220.

The pin terminals 220 are terminals for connecting the tester 300 and the probe card 200. Each of the pin terminals 220 is connected to the probe substrate 210 through the signal line 219 and is connected to the tester 300 through the signal line 229. The probe substrate 210 is a substrate on which a plurality of probes are provided.

Here, a shape of the probe card 200 is a shape having two facing planar surfaces such as a disk shape and the like, and probes are provided on one of these planar surfaces, and the pin terminals 220 are provided on the other surface.

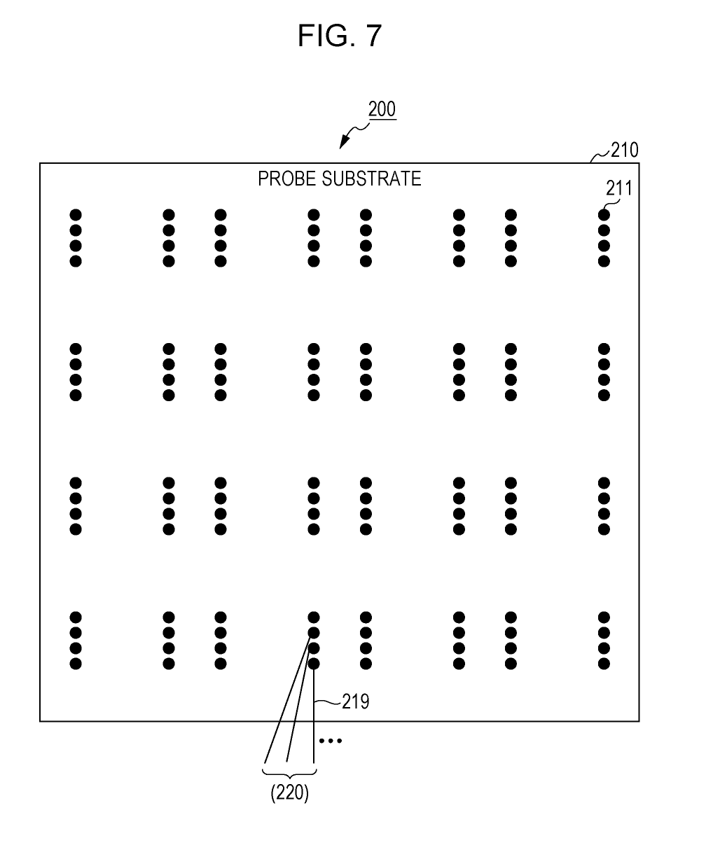

FIG. 7 is an example of the plan view of the probe substrate 210 in the first embodiment. A plurality of probes 211 are provided on the probe substrate 210. These probes 211 are provided only at positions corresponding to the electrode pads used in a test among the electrode pads on the semiconductor chips 110 in the test area 160. For example, when using only electrode pads along two sides which are parallel to each other among the four sides of the semiconductor chips 110 are used in the test, the probes 211 are provided at positions corresponding to these electrode pads. Any one of the pin terminals 220 is connected to each of these probes 211 through the signal line 219.

As exemplified in FIG. 7, since the probes 211 are provided in electrode pads of some of the semiconductor chips 110, a density of the probes 211 on the probe card 200 is less than a density when providing the probes 211 on all of the electrode pads of the semiconductor chips 110. Therefore, a wiring which connects the probes 211 and the pin terminals 220 is simplified to relax a constraint to provide the probes. As a result, it is possible to increase the number of the semiconductor chips 110 which are measured at the same time. Accordingly, a test can be efficiently performed, so that it is possible to reduce time necessary for a test.

In this manner, according to the first embodiment of the present technology, since the semiconductor chips 110 control a value of the input signal IN from the signal cells which are not used in the test to be predetermined value, it is possible to prevent the undetermined value from being input to the test circuit 151 and the like. Accordingly, the test system can acquire an appropriate test result in the wafer test.

### First Modification Example

In the first embodiment, the signal cells 140 which invalidate an input signal according to an enable signal are provided in the semiconductor chips 110; however, the signal cells 140 which do not have a function of invalidating an input signal may be provided. The semiconductor chips 110 of the first modification example are different from those of the first embodiment in that the semiconductor chips 110 of the first modification example provide the signal cells 140 which do not have the function of invalidating an input signal.

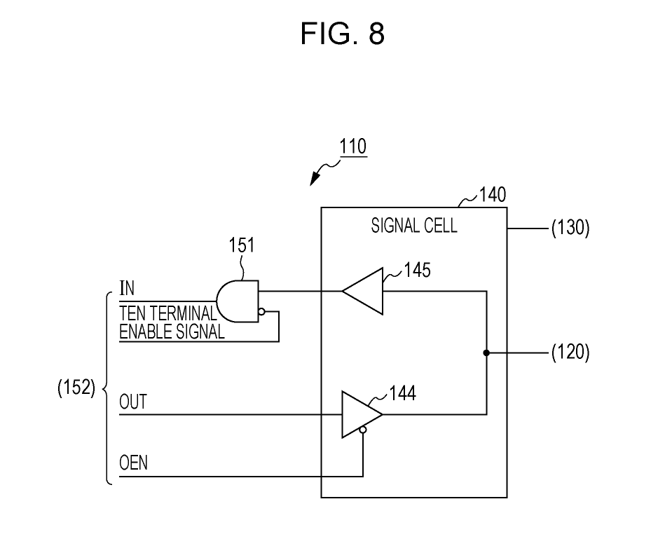

FIG. 8 is a circuit diagram which shows a configuration example of semiconductor chips 110 of the first modification example. The semiconductor chips 110 in the modification example are different from those of the first embodiment in that the semiconductor chips in the modification example include the AND gate 141, the switch 142, and a buffer 145 instead of the pull resistance 143 in the signal cell 140.

The buffer 145 outputs an input signal IN from the electrode pads 120 to an input terminal of the AND gate 153.

In this manner, according to the first modification example, since a circuit which invalidates an input signal may not be provided in the signal cells 140, it is possible to simplify a circuit configuration of the signal cells 140.

### Second Modification Example

In the first embodiment, the enable signal generating circuit 154 is provided in the internal circuit 150; however, the enable signal generating circuit 154 may not be provided in the internal circuit 150. The semiconductor chips 110 of the second modification example are different from those of the first embodiment in that the enable signal generating circuit 154 is not provided in the internal circuit 150.

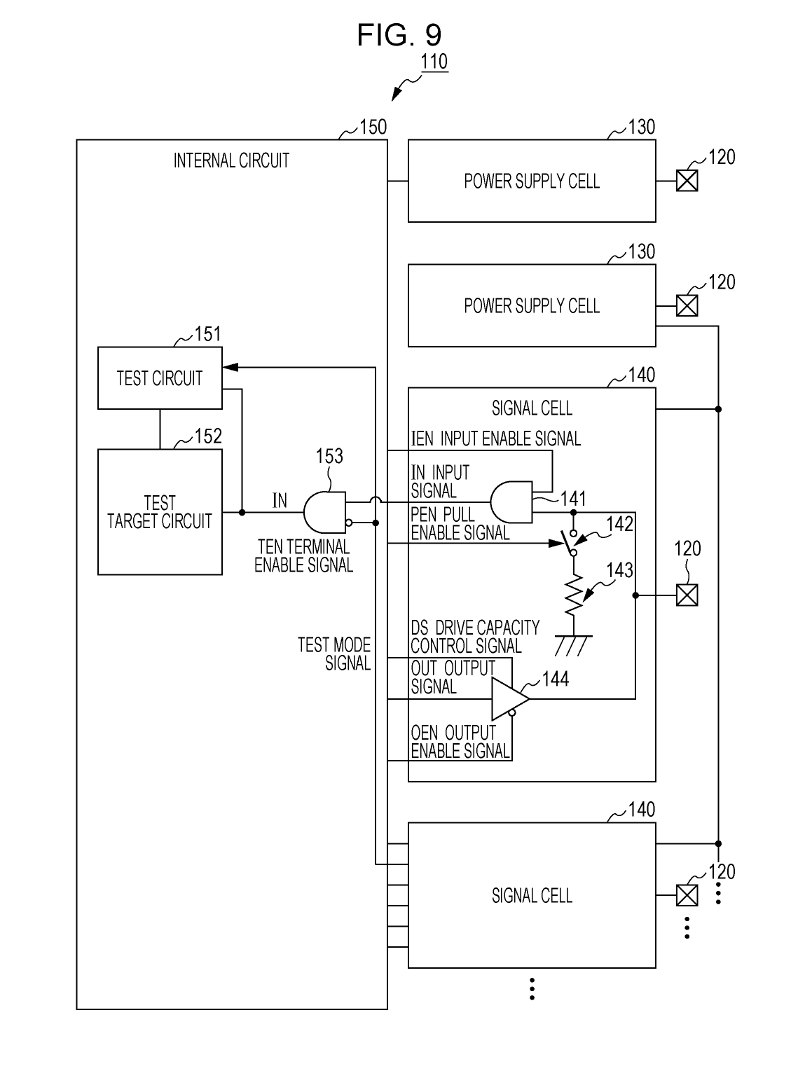

FIG. 9 is a circuit diagram which shows a configuration example of the semiconductor chips 110 of the second modification example. The semiconductor chips 110 of the second modification example are different from those of the first embodiment in that the semiconductor chips 110 of the second modification example do not include the enable signal generating circuit 154. The tester 300 of the second modification example generates a test mode signal, and supplies the test mode signal to the AND gate 153 and the test circuit 151 through the probe card 200, the electrode pads 13 and the signal cells 140. For example, the test mode signal is set to be a high level in a period performing a wafer test, and is set to a low level in the other periods.

The test circuit 151 performs a test by using the input signal IN from the signal cells 140 used in the test in a period in which the test mode signal is at a high level.

The above-described embodiment shows an example for embodying the present technology, and matters of the embodiments have a corresponding relationship with respective technology identification matters of the claims. In the same manner, the technology identification matters of the claims have a corresponding relationship with the matters of the embodiments of the present technology which are respectively given the same name as the technology identification matters. However, the technology is not limited to the embodiments, but it is possible to embody the technology by variously modifying the embodiments in a scope without departing from a spirit of the present technology.

In addition, processing procedures described in the above-described embodiments may be considered as a method having a series of these procedures, and may be considered as a program for causing a computer to perform the series of these procedures or a recording medium which stores the program. As the recording medium, for example, a Compact Disc (CD), a MiniDisc (MD), a Digital Versatile Disc (DVD), a memory card, a Blu-ray disc (registered trademark) and the like can be used.

Effects described herein are not necessarily limited, but may be any effect described in the present disclosure.

The present technology can adopt a configuration as follows.

(1) A semiconductor integrated circuit includes:

a test circuit which performs a predetermined test on a test target circuit;

a plurality of signal cells which input an input signal into the test circuit and the test target circuit;

a power supply cell which supplies power to some of the plurality of signal cells in the test; and

a control circuit which controls a value of the input signal from the signal cells that include signal cells to which the power is not supplied and that are not used in the test, to be a predetermined value.

(2) The semiconductor integrated circuit described in (1),

in which the semiconductor integrated circuit is provided in a semiconductor chip of a rectangular shape,

the plurality of signal cells are arrayed along each of four sides of the semiconductor chip, and

the power supply cell supplies the power to the signal cell arrayed along at least one of two sides of the semiconductor chip.

(3) The semiconductor integrated circuit described in (1) or (2),

in which the test target circuit generates a control signal which instructs to control the input signal to be the predetermined value, and an output signal to supply these signals to the signal cell, and

the signal cell controls the input signal to be the predetermined value according to the control signal to output the output signal.

(4) A test system includes:

a test circuit which performs a predetermined test on a test target circuit;

a plurality of signal cells which input an input signal to the test circuit and the test target circuit;

a power supply cell which supplies power to some of the plurality of signal cells in the test;

a control circuit which controls a value of the input signal from the signal cells that include signal cells to which the power is not supplied and that are not used in a test, to be a predetermined value; and

a probe card on which probes are provided at a position corresponding to each of some of the plurality of signal cells and the power supply cell.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor integrated circuit comprising:
a test circuit which performs a predetermined test on a test target circuit;
a plurality of signal cells which input an input signal into the test circuit and the test target circuit;
a power supply cell which supplies power to some of the plurality of signal cells in the test; and
a control circuit which controls a value of the input signal from signal cells that include signal cells to which the power is not supplied and that are not used in the test, to be a predetermined value.

2. The semiconductor integrated circuit according to claim 1,
wherein the semiconductor integrated circuit is provided in a semiconductor chip of a rectangular shape,
the plurality of signal cells are arrayed along each of four sides of the semiconductor chip, and
the power supply cell supplies the power to the signal cell arrayed along at least one of two sides of the semiconductor chip.

3. The semiconductor integrated circuit according to claim 1,
wherein the test target circuit generates a control signal which instructs to control the input signal to be the predetermined value, and an output signal to supply these signals to the signal cell, and
the signal cell controls the input signal to be the predetermined value according to the control signal to output the output signal.

4. A test system comprising:
a test circuit which performs a predetermined test on a test target circuit;
a plurality of signal cells which input an input signal to the test circuit and the test target circuit;
a power supply cell which supplies power to some of the plurality of signal cells in the test;
a control circuit which controls a value of the input signal from the signal cells that include signal cells to which the power is not supplied and that are not used in a test, to be a predetermined value; and
a probe card on which probes are provided at a position corresponding to each of some of the plurality of signal cells and the power supply cell.
